(19) United States
(12) Patent Application Publication
(10) Pub. No.: US 2011/0108808 A1
(43) Pub. Date: May 12, 2011

(54) Organic Light Emitting Diode Display

(75) Inventor: Eun-Ah Kim, Yongin-City (KR)

(73) Assignee: SAMSUNG MOBILE DISPLAY CO., LTD.

(21) Appl. No.: 12/852,206

(22) Filed: Aug. 6, 2010

(30) Foreign Application Priority Data
Nov. 10, 2009 (KR) 10-2009-0108268

(51) Int. Cl. H01L 51/50

(52) U.S. Cl. 257/40; 257/E51.022

(57) ABSTRACT

An organic light emitting diode display that includes a first substrate including an organic light emitting diode, a second substrate having a receiving unit formed by recession of one surface facing the first substrate and bonded with the first substrate to cover the organic light emitting diode, a first optical member attached to the other surface opposite to the one surface facing the first substrate between both surfaces of the second substrate, and a second optical member received in the receiving unit of the second substrate.

### RELATED APPLICATIONS

This application claims priority to and the benefit of Korean Patent Application No. 10-2009-0108268 filed in the Korean Intellectual Property Office on Nov. 10, 2009, the entire contents of which are incorporated herein by reference.

### BACKGROUND

1. Field

The general inventive concept relates to an organic light emitting diode display.

2. Description of the Related Art

An organic light emitting diode display is a self-emissive display device that has an organic light emitting diode that emits light to display an image. Since the organic light emitting diode display does not require an additional light source, unlike a liquid crystal display, it is possible to comparatively reduce thickness and weight thereof. Further, the organic light emitting diode display has high-quality characteristics such as low power consumption, high luminance, and high reaction speed, such that it is gaining more and more attention as a next-generation display device for portable electronic devices.

The above information disclosed in this Related Art section is only for enhancement of understanding of the background of the described technology and therefore it may contain information that does not form the prior art that is already known in this country to a person of ordinary skill in the art.

### SUMMARY

The described technology has been made in an effort to provide an organic light emitting diode display having an overall slim thickness.

An exemplary aspect of the invention provides for an organic light emitting diode display that includes a first substrate including an organic light emitting diode; a second substrate having a receiving unit formed by recession/indentation of one surface facing the first substrate and bonded with the first substrate to cover the organic light emitting diode; a first optical member attached to the other surface opposite to the one surface facing the first substrate between both surfaces of the second substrate; and a second optical member received in the receiving unit of the second substrate.

The first optical member may be a polarization film and the second optical member may be a phase retardation film.

The receiving unit of the second substrate and the second optical member may have larger dimensions than an area where the organic light emitting diode is formed.

The receiving unit of the second substrate may be formed through an etching process.

The second optical member may be made of a material that is comparatively softer than the second substrate.

The organic light emitting diode may emit light in the direction of the second substrate.

The organic light emitting diode display may further include a sealant that is disposed on edges of the first substrate and the second substrate to bond the first substrate and the second substrate to each other for sealing.

The organic light emitting diode display may further include an outer surface adhesive layer disposed between the first optical member and the second substrate.

The organic light emitting diode display may further include an inner surface adhesive layer disposed between the second optical member and the second substrate in the receiving unit.

According to an aspect of the invention, an organic light emitting diode display can have an overall slim thickness.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an organic light emitting diode display according to one embodiment;

FIG. 2 is a layout view illustrating a circuit layout of a driving circuit unit and an organic light emitting diode of an organic light emitting diode display of FIG. 1; and

FIG. 3 is a partial enlarged cross-sectional view of an organic light emitting diode display taken along line of FIG. 2.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.
Accordingly, the drawings and description are to be regarded as illustrative in nature and not restrictive. Like reference numerals designate like elements throughout the specification.

In addition, the size and thickness of each component shown in the drawings are arbitrarily shown for understanding and ease of description, but the present invention is not limited thereto.

In the drawings, the thickness of layers, regions, etc., are exaggerated for clarity. In the drawings, for understanding and ease of description, the thickness of some layers and areas is exaggerated. It will be understood that when an element such as a layer, film, region, or substrate is referred to as being “on” another element, it can be directly on the other element or intervening elements may also be present.

In general, in a conventional organic light emitting diode display, external light is reflected by an electrode of the organic light emitting diode, such that expression of a black color and contrast are deteriorated. The organic light emitting diode display is additionally provided with optical members such as a polarization film and a phase retardation film in order to suppress reflection of the external light.

Each of the optical members is generally attached to an outer surface of a substrate through an adhesive layer. Accordingly, the organic light emitting diode display having optical films is as thick as the optical films and the adhesive layers.

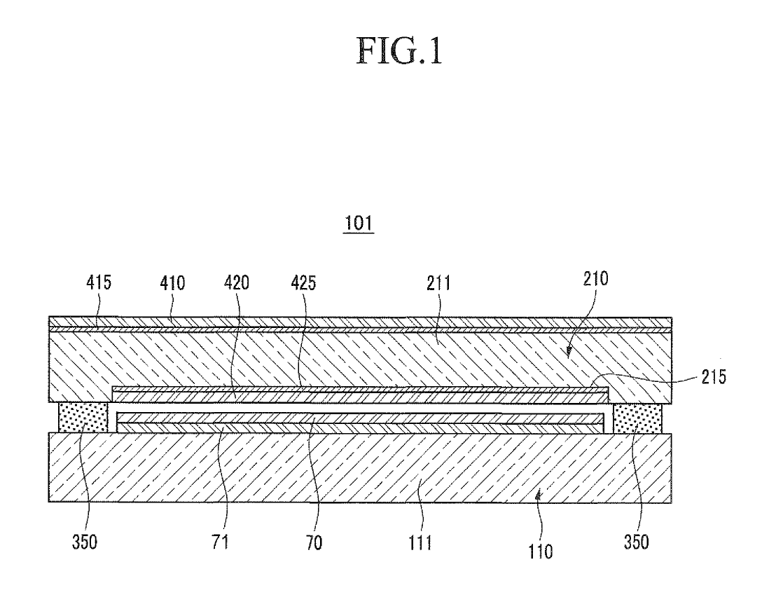

Hereinafter, one embodiment will be described with reference to FIGS. 1 to 3.

As shown in FIG. 1, the organic light emitting diode display 101 constructed as one embodiment includes a first substrate 110, a second substrate 210, a first optical member 410, and a second optical member 420. In addition, the organic light emitting diode display 101 further includes an outer surface adhesive layer 415, an inner surface adhesive layer 425, and a sealant 350.

The first substrate 110 includes a first substrate body 111, and a driving circuit 71 and an organic light emitting diode 70 that are formed on the first substrate body 111.

The first substrate body 111 may be formed of an insulating substrate that is made of glass, quartz, ceramic, plastic, etc. However, this exemplary embodiment is not limited thereto, and the first substrate body 111 may be formed by a metallic substrate that is made of stainless steel, etc.

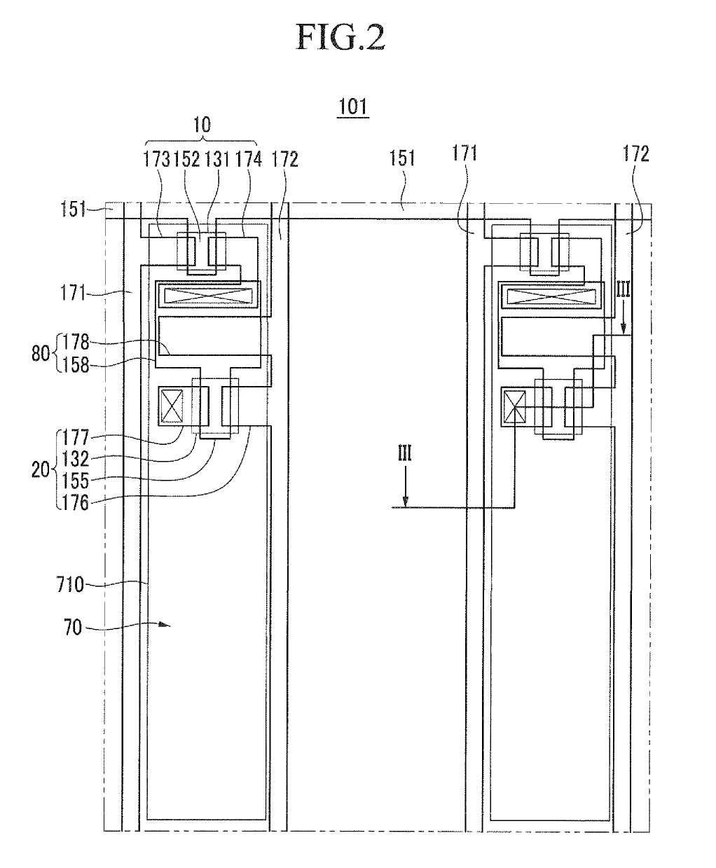

The driving circuit 71 includes thin film transistors 10 and 20 (shown in FIG. 2), and drives the organic light emitting diode 70. The organic light emitting diode 70 emits light in response to a driving signal received from the driving circuit 71 to display an image.

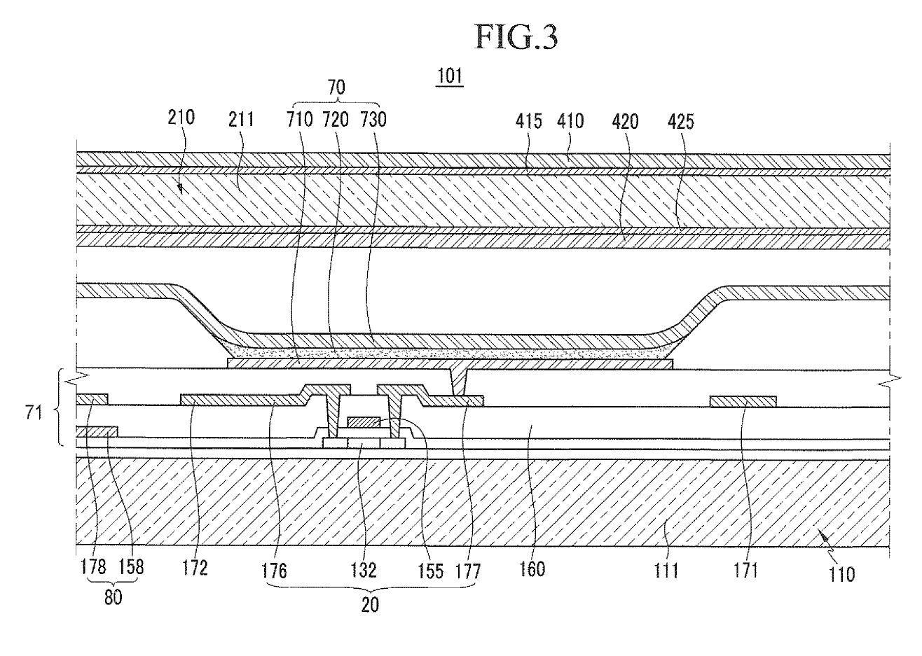

Detailed structures of the organic light emitting diode 70 and the driving circuit 71 are shown in FIGS. 2 and 3, but the structures of the organic light emitting diode 70 and the driving circuit 71 are not limited to the structures shown in FIGS. 2 and 3. The organic light emitting diode 70 and the driving circuit 71 may be formed in various structures within a scope that can be easily modified by those skilled in the art.

However, the organic light emitting diode 70 emits light in the direction of the second substrate 210, and the organic light emitting diode display 101 displays the image in the direction of the second substrate 210.

The second substrate 210 is spaced from and opposed to the first substrate 110 to cover the organic light emitting diode 70 and the driving circuit 71 of the first substrate 110. In addition, the first substrate 110 and the second substrate 210 are bonded with each other to seal a space therebetween. Herein, the sealant 350 is disposed on edges of the first substrate 110 and the second substrate 210, such that the first substrate 110 and the second substrate 210 are sealed by being bonded with each other. The sealant 350 may be made of various kinds of materials known to those skilled in the art.

The second substrate 210 includes a second substrate body 211 and a receiving unit 215 formed by recession/indentation/depression of one surface of the second substrate body 211 that faces the first substrate 110. Herein, the receiving unit 215 of the second substrate 210 is formed by removing a part of the second substrate body 211 through an etching process. Further, the receiving unit 215 of the second substrate 210 has larger dimensions than an area where the organic light emitting diode 70 of the first substrate 110 is formed.

Further, the second substrate 210 is made of a transparent material such as glass, plastic, etc.

The first optical member 410 is attached to the other surface that is opposite to one surface that faces the first substrate 110 between both surfaces of the second substrate body 211. In addition, a polarization film is used as the first optical member 410. The polarization film transmits light in the same axis direction as a polarization axis of the polarization film, and absorbs the other light. That is, the light penetrating the polarization film is linearly polarized. Various kinds of polarization films known to those skilled in the art may be used as the polarization film used as the first optical member 410. For example, the first optical member 410 may be made of tri-acetate cellulose (TAC), poly vinyl alcohol, etc.

The second optical member 420 is received in the receiving unit 215 of the second substrate 210. In addition, a phase retardation film is used as the second optical member 420. The phase retardation film circularly polarizes the linearly polarized light that penetrates the first optical member 410. Various kinds of phase retardation films known to those skilled in the art may be used as the phase retardation film used as the second optical member 420. For example, the second optical member 420 may be made of a material including a polycarbonate.

Both the first optical member 410 and the second optical member 420 suppress reflection of light introduced into the organic light emitting diode display 101 from the outside. As such, when reflection of external light is suppressed, the organic light emitting diode display 101 improves visibility and improves display characteristics such as expression of a black color, better contrast, etc.

Hereinafter, an operation effect of the first optical member 410 which is the polarization film and the second optical member 420 which is the phase retardation film that suppress the external light reflection will be described in detail.

As an example, under the assumption that the first optical member 410 is the polarization film having a horizontal polarization axis, the external light is linearly polarized in a horizontal direction while passing through the first optical member 410. The horizontally linearly-polarized light is right-circularly polarized while passing through the second optical member 420. Herein, the light passing through the second optical member 420 may be left-circularly polarized depending on the kind of the phase-retardation film used.

Next, the right-circularly polarized light has a changed phase of the left-circularly polarized light while being reflected by a reflective material of the organic light emitting diode 70 or the driving circuit 71. The light that is left-circularly polarized through reflection is changed into vertically linearly-polarized light while again passing through the second optical member 420 which is the phase retardation film. As such, since the vertically linearly-polarized light does not pass through the first optical member 410 having the horizontal polarization axis, the organic light emitting diode display 101 may prevent the external light from being reflected.

Further, the second optical member 420 has dimensions that are relatively larger than an area where the organic light emitting diode 70 of the first substrate 110 is formed. In addition, the second optical member 420 is made of a material that is relatively softer than the second substrate 210.

In the case where a gap between the second substrate 210 and the first substrate 110 becomes narrow by external pressure, the second optical member 420 may partially contact the organic light emitting diode 70 of the first substrate 110. However, since the second optical member 420 is made of a material that is relatively softer than the second substrate 210, the second optical member 420 is not disposed between the second substrate 210 and the organic light emitting diode 70, thereby reducing damage to the organic light emitting diode 70 in comparison with a case where the second substrate 210 directly contacts the organic light emitting diode 70. That is, the second optical member 420 also serves to protect the organic light emitting diode 70.

The receiving unit 215 of the second substrate 210 is comparatively larger than the area where the organic light emitting diode 70 is formed, such that the second optical member 420 is larger than the organic light emitting diode 70. The second optical member 420 is larger than the area where the organic light emitting diode 70 is formed, such that it is possible to prevent the organic light emitting diode 70 from being damaged.

The outer surface adhesive layer 415 is disposed between the second substrate 210 and the first optical member 410, such that the second substrate 210 and the first optical member 410 are coupled with each other. The inner surface adhesive layer 425 is disposed between the second optical member 420 and the second substrate 210 in the receiving unit 215, such that the second substrate 210 and the second optical member 420 are coupled with each other. In addition, the outer surface adhesive layer 415 and the inner surface adhesive layer 425 may be made of various kinds of materials known to those skilled in the art. For example, the outer surface adhesive layer 415 and the inner surface adhesive layer 425 may be made of a material including a methylacrylate.

By this configuration, the organic light emitting diode display 101 can minimize an increase of the overall thickness while including the first optical member 410 and the second optical member 420. That is, the second optical member 420 is disposed in the recessed receiving unit 215 of the second substrate 210, such that it is possible to prevent the thickness from being increased due to the second optical member 420. That is, it is possible to prevent the entire thickness of the organic light emitting diode display 101 from being increased the depth in which the receiving unit 215 of the second substrate 210 is recessed increases with the thickness of the second optical member 420.

Further, the organic light emitting diode display 101 can suppress the external light reflection by using the polarization film as the first optical member 410 and the phase retardation film as the second optical member 420.

Further, in the organic light emitting diode display 101, the second optical member 420 is disposed between the second substrate 210 and the organic light emitting diode 70 of the first substrate 110, such that it is possible to prevent the organic light emitting diode 70 from being damaged.

Further, in this embodiment, the first optical member 410 is necessarily limited to the polarization film but the second optical member 420 is not limited to the phase retardation film. Accordingly, various kinds of optical films having a function to improve the luminance or color purity of the organic light emitting diode display 101 or a mirror function may be used as the first optical member 410 and the second optical member 420.

Hereinafter, an internal structure of the organic light emitting diode display 101 will be described in detail with reference to FIGS. 2 and 3. FIG. 2 illustrates a structure of a pixel on the basis of the first substrate 110. Herein, the pixel represents a minimum unit for displaying an image. The organic light emitting diode display 101 displays the image through a plurality of pixels. FIG. 3 is a cross-sectional view of the organic light emitting diode display 101 taken along line of FIG. 2.

As shown in FIGS. 2 and 3, the first substrate 110 includes a switching thin film transistor 10, a driving thin film transistor 20, a storage capacitor 80, and the organic light emitting diode (OLED) 70 that are formed for each pixel. Herein, a configuration including the switching thin film transistor 10, the driving thin film transistor 20, and the storage capacitor 80 is referred to as the driving circuit 71. In addition, the first substrate 110 further includes a gate line 151 disposed in one direction, a data line 171 insulatively crossing the gate line 151, and a common power line 172. Herein, a boundary of one pixel may be defined by the gate line 151, the data line 171, and the common power line 172, but is not limited thereto.

The organic light emitting diode 70 includes a pixel electrode 710, an organic emission layer 720 formed on the pixel electrode 710, and a common electrode 730 formed on the organic emission layer 720. Herein, the pixel electrode 710 is a positive (+) electrode which is a hole injection electrode, and the common electrode 730 is a negative (−) electrode which is an electron injection electrode. However, the first exemplary embodiment is not limited thereto. Therefore, the pixel electrode 710 may be the negative electrode or the common electrode 730 may be the positive electrode according to a driving method of the organic light emitting diode display 101. Holes and electrodes are injected into the organic emission layer 720 from each of the pixel electrode 710 and the common electrode 730. When excitons generated by combination of the injected holes and electrons in the organic emission layer are transitioned from an excited state to a ground state, light is emitted.

Further, in the organic light emitting diode display 101 according to the exemplary embodiment, the organic light emitting diode 70 emits light in the direction of the second substrate 210. That is, the organic light emitting diode 70 is a top emission type. Herein, for the organic light emitting diode 70 to emit light in the direction of the second substrate 210, a reflective electrode is used as the pixel electrode 710 and a transmissive or semi-transmissive electrode is used as the common electrode 730.

The storage capacitor 80 includes a pair of capacitor plates 158 and 178 with an interlayer insulating layer 160 interposed therebetween. Herein, the interlayer insulating layer 160 becomes a dielectric. Storage capacity is determined by electric charges stored in the storage capacitor 80 and a voltage between both the capacitor plates 158 and 178.

The switching thin film transistor 10 includes a switching semiconductor layer 131, a switching gate electrode 152, a switching source electrode 173, and a switching drain electrode 174. The driving thin film transistor 20 includes a driving semiconductor layer 132, a driving gate electrode 155, a driving source electrode 176, and a driving drain electrode 177.

The switching thin film transistor 10 serves as a switching element that selects a desired pixel to emit light. The switching gate electrode 152 is connected to the gate line 151. The switching source electrode 173 is connected to the data line 171. The switching drain electrode 174 is disposed away from the switching source electrode 173 and connected to any one storage plate (158 in this case).

The driving thin film transistor 20 applies driving power for allowing the organic emission layer 720 of the organic light emitting diode 70 in the selected pixel to emit light to the pixel electrode 710. The driving gate electrode 155 is connected to the storage plate 158 connected with the switching drain electrode 174. Each of the driving source electrode 176 and the other storage plate 178 is connected to the common power supply line 172. The driving drain electrode 177 is connected to the pixel electrode 710 of the organic light emitting diode 70 through a contact hole.

By this structure, the switching thin film transistor 10 is operated by a gate voltage applied to the gate line 151 serving to transmit a data voltage applied to the data line 171 to the driving thin film transistor 20. A voltage corresponding to a difference between a common voltage applied to the driving thin film transistor 20 from the common power supply line 172 and the data voltage transmitted from the switching thin film transistor 10 is stored in the storage capacitor 80, and a current corresponding to the voltage stored in the storage capacitor 80 flows to the organic light emitting diode 70 through the driving thin film transistor 20 to allow the organic light emitting diode 70 to emit light.

As shown in FIG. 3, the second substrate 210 is disposed on the organic light emitting diode 70 to protect the organic light emitting diode 70. The first optical member 410 is disposed outside of the second substrate 210 and the second optical member 420 is disposed inside of the second substrate 210 to suppress the external light reflection.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a first substrate including an organic light emitting diode;
a second substrate having a receiving unit formed by recession of one surface facing the first substrate and bonded with the first substrate to cover the organic light emitting diode;
a first optical member attached to the other surface opposite to the one surface facing the first substrate between both surfaces of the second substrate; and
a second optical member received in the receiving unit of the second substrate.

2. The organic light emitting diode display of claim 1, wherein
the first optical member is a polarization film and the second optical member is a phase retardation film.

3. The organic light emitting diode display of claim 1, wherein
the receiving unit of the second substrate and the second optical member has larger dimensions than an area where the organic light emitting diode is formed.

4. The organic light emitting diode display of claim 1, wherein
the receiving unit of the second substrate is formed through an etching process.

5. The organic light emitting diode display of claim 1, wherein
the second optical member is made of a material that is comparatively softer than the second substrate.

6. The organic light emitting diode display of claim 1, wherein
the organic light emitting diode emits light in a direction toward the second substrate.

7. The organic light emitting diode display of claim 1, further comprising
a sealant that is disposed on edges of the first substrate and the second substrate to bond the first substrate and the second substrate with each other.

8. The organic light emitting diode display of claim 1, further comprising
an outer surface adhesive layer disposed between the first optical member and the second substrate.

9. The organic light emitting diode display of claim 1, further comprising
an inner surface adhesive layer disposed between the second optical member and the second substrate in the receiving unit.

10. An organic light emitting diode display, comprising:
a first substrate including an organic light emitting diode;
a second substrate having a receiving unit formed in an indentation on one surface facing the first substrate and bonded with the first substrate to cover the organic light emitting diode;
a first optical member attached to the other surface opposite to the one surface facing the first substrate between both surfaces of the second substrate; and
a second optical member contained entirely in the receiving unit of the second substrate,
wherein the receiving unit of the second substrate and the second optical member has a larger dimensional area than a dimensional area where the organic light emitting diode is formed,
wherein a space exists between the organic light emitting diode and the second optical member.

11. The organic light emitting diode display of claim 10, wherein the first optical member is a polarization film and the second optical member is a phase retardation film.

12. The organic light emitting diode display of claim 10, wherein the receiving unit of the second substrate is formed through an etching process.

13. The organic light emitting diode display of claim 10, wherein the second optical member is made of a material that is comparatively softer than the second substrate.

14. The organic light emitting diode display of claim 10, wherein the organic light emitting diode emits light in the direction of the second substrate.

15. The organic light emitting diode display of claim 10, further comprising:
a sealant that is disposed on edges of the first substrate and the second substrate to bond the first substrate and the second substrate with each other for sealing.

16. The organic light emitting diode display of claim 10, further comprising:
an outer surface adhesive layer disposed between the first optical member and the second substrate.

17. The organic light emitting diode display of claim 10, further comprising: an inner surface adhesive layer disposed between the second optical member and the second substrate in the receiving unit.
